(19) United States
(12) Patent Application Publication
(10) Pub. No.: US 2006/0071836 A1
(43) Pub. Date: Apr. 6, 2006

(54) Digital to analog converter

(75) Inventors: Takashige Ogata, Gunma (JP); Tatsuya Suzuki, Saitama (JP)

Correspondence Address: MORRISON & FOERSTER LLP, 1650 TYSONS BOULEVARD, SUITE 300, MCLEAN, VA, 22102, US

(73) Assignee: SANYO ELECTRIC CO., LTD., Moriguchi-shi (JP)

(21) Appl. No.: 11/212,917

(22) Filed: Aug. 29, 2005

(30) Foreign Application Priority Data
Aug. 30, 2004 (JP) 2004-250575

(51) Int. Cl. H03M 1/66

(52) U.S. Cl. 341/144

(57) ABSTRACT

An output voltage proportional to a duty ratio of a PWM signal can be obtained without using a large-scale circuit, even when a high potential (input potential) of an inverter is low. The digital to analog converter includes a CMOS inverter where a PWM signal generated from a pulse width modulation circuit is inputted, and a low-pass filer supplied with an output of a CMOS inverter. The CMOS inverter includes a P-channel type first MOS transistor and a N-channel type second MOS transistor connected in serial between an input potential and a ground potential, where the PWM signal is applied to each of gates, and an N-channel type third MOS transistor connected with the P-channel type first MOS transistor in parallel and forming a CMOS transmission gate together with the P-channel type first MOS transistor.

### CROSS-REFERENCE OF THE INVENTION

This invention is based on Japanese Patent Application No. 2004-250575, the content of which is incorporated by reference in its entirety.

### BACKGROUND OF THE INVENTION

1. Field of the Invention

This invention relates to a digital to analog converter applicable to digital AV equipment and so on.

2. Description of the Related Art

Conventionally, a digital to analog converter outputs an analog voltage proportional to a duty ratio of a pulse having a pulse width corresponding to the size of digital data. This pulse is generated by a pulse width modulation (PWM) circuit and hereafter referred to as a PWM signal.

FIG. 3 shows a circuit diagram of such a digital to analog converter. A numeral 50 designates an input terminal where digital data is applied, a numeral 51 designates a PWM circuit which performs pulse width modulation to the digital data and outputs a PWM signal, and a numeral 52 designates a switch for switching to output an input potential Vin or a ground potential Vss (0V) to a low-pass filter 53 according to a level of the PWM signal. The low-pass filter 53 is formed of a resistor 54 and a capacitor 55. High frequency components of the output of the switch 52 is removed through the low-pass filter 53, and an output signal Vout is obtained from an output terminal 56.

An operation of this digital to analog converter will be described with reference to FIGS. 4A, 4B, and 5. As shown in FIG. 4A, a state where an input potential Vin is applied to the low-pass filter 53 by the switch 52 when the PWM signal is high level is referred to as a phase 1. As shown in FIG. 4B, a state where a ground potential Vss is applied to the low-pass filter 53 by the switch 52 when the PWM signal is low level is referred to as a phase 2. Alternating the phase 1 and the phase 2 until the circuit is stabilized, a charge amount ΔQ1 flowing in the capacitor 55 on the phase 1 and a charge amount ΔQ2 flowing out of the capacitor 55 on the phase 2 become equal, and a voltage proportional to the duty ratio of the PWM signal is generated as an output voltage Vout.

The following equations establish that the output voltage Vout is proportional to the duty ratio of the PWM signal. Suppose that a PWM signal having a cycle t and a duty ratio n is outputted from the pulse width modulation circuit 51 as shown in FIG. 5 and the phase 1 and the phase 2 are repeated until the circuit is stabilized. Note that “n” is a number between 0 and 1, and the pulse is maintained for the period of “t”×“n.” On the phase 1, suppose that a current I1 flows in the capacitor 55 and the capacitor 55 is charged, so that the output voltage Vout varies by ΔV1. When ΔV1 is low enough and the variation of the current I1 caused by ΔV1 is negligible, the following equation (1) is established.
I1=(Vin−Vout)/R (1)

In this equation, R indicates a resistance value of the resistor 54. A period of the high level of the PWM signal is t·n, so that ΔQ1 is expressed by the following equation (2).
ΔQ1=I1·t·n=(Vin−Vout)t·n/R (2)

The following equation (3) is established for the capacitor 55.
ΔQ1=C·ΔV1 (3)

In this equation, C indicates a capacitance value of the capacitor 55. The following equation (4) can be established from the equations (2) and (3).
C·ΔV1=(Vin−Vout)t·n/R (4)

When the equation (4) is solved for ΔV1, the following equation (5) is established.
ΔV1=(Vin−Vout)t·n/(C·R) (5)

Next, the PWM signal becomes low level, shifting to the phase 2. At this time, suppose that a current I2 flows out of the capacitor 55 and the capacitor 55 is discharged, so that the output voltage varies by ΔV2. When ΔV2 is low enough and the variation of the current I2 caused by ΔV2 is negligible, the following equation (6) is established.
I2=Vout/R (6)

Since a period of the low level of the PWM signal is t·(1−n), a charge amount ΔQ2 flowing in the capacitor 55 is expressed by the following equation by assigning the equation (6).
ΔQ2=I2·t·(1−n)=Vout·t·(1−n)/R (7)

Furthermore, the following equation (8) is established for the capacitor 55.
ΔQ2=C·ΔV2 (8)

Therefore, the following equation (9) is established from the equations (7) and (8).
C·ΔV2=Vout·t·(1−n)/R (9)

By solving the equation (9) for ΔV2, the following equation (10) is established.
ΔV2=Vout·t·(1−n)/(C·R) (10)

When the circuit is stabilized, the following equation (11) is established.
ΔV1=ΔV2 (11)

When the equations (5) and (10) are plugged into the equation (11), the following equation (12) is established.
(Vin−Vout)t·n/(C·R)=Vout·t·(1−n)/(C·R) (12)

When the equation (12) is solved, the following equation is established.
Vout=n·Vin (13)

Thus, the output voltage Vout proportional to the duty ratio n of the PWM signal is obtained.

As shown in FIG. 6, a circuit where the switch 52 of the circuit shown in FIG. 3 is formed of a CMOS inverter 60 has been known. This is disclosed in Japanese Patent Application Publication No. Hei 6-77833. In this case, for making the circuit equivalent to the circuit shown in FIG. 3, an inverter 61 for inverting the PWM signal outputted from the pulse width modulation circuit 51 is added to this circuit. In this circuit, when the PWM signal is high level, a P-channel type MOS transistor M1 of the CMOS inverter 60 turns on, shifting to the phase 1 shown in FIG. 4A. When the PWM signal is low level, an N-channel type MOS transistor M2 of the CMOS inverter 60 turns on when the PWM signal is low level, shifting to the phase 2 shown in FIG. 4B. The high level of the PWM signal is Vdd, and the low level is 0V. A power supply of the inverter 61 on a high potential side is Vdd, and a power supply thereof on a low potential side is 0V. A power supply of the CMOS inverter 60 on a high potential side is Vin, and a power supply thereof on a low potential side is 0V.

As shown in FIG. 7, a voltage VGS between a gate and a source when the P-channel type MOS transistor M1 of the CMOS inverter 60 turns on is equal to a value of the input potential Vin. Then, in the circuit shown in FIG. 6, VGS when the P-channel type MOS transistor M1 turns on becomes lower as the input potential Vin becomes lower, so that on-state resistance can not be neglected.

When the on-state resistance of the P-channel type MOS transistor M1 is indicated by Rp, the equation (1) is replaced with the following equation (1A).
I1I=(Vin−Vout)/(R+Rp) (1A)

Therefore, the equation (13) is replaced with the following equation (13A).
Vout=n·R/((1−n)·(R+Rp)+n·R)×Vin (13A)

Then, the output voltage Vout proportional to the duty ratio n of the PWM signal can not be obtained.

FIGS. 8A and 8B show simulation results showing a relation between the output voltage Vout and the duty ratio n (%) of the PWM signal in the circuit shown in FIG. 6. Vdd=3V, R=1 MΩ, and PWM cycle=1 μs are set as a common condition.

In FIG. 8A, where Vin=3V, the ideal output voltage Vout proportional to the duty ratio of the PWM signal can be obtained. However, in FIG. 8B, where Vin=1V, the output voltage Vout is out of the ideal characteristics.

For obtaining the output voltage Vout proportional to the duty ratio n even when the input potential Vin is low, an integrator with an amplifier may be added to the circuit. However, there is a problem of forming a large-scale circuit.

### SUMMARY OF THE INVENTION

The invention provides a digital to analog converter that includes a pulse width modulation circuit generating a pulse having a pulse width corresponding to digital data received by the pulse width modulation circuit, an inverter receiving the pulse generated by the pulse width modulation circuit, and a low-pass filter receiving an output of the inverter. The inverter includes a P-channel type MOS transistor and a first N-channel type MOS transistor that are connected in series between a high potential and a low potential. The pulse is applied to gates of the P-channel type MOS transistor and the first N-channel type MOS transistor. The inverter further includes a second N-channel type MOS transistor that is connected with the P-channel type MOS transistor in parallel to form a CMOS transmission gate having the P-channel type MOS transistor and the second N-channel type MOS transistor.

### BRIEF DESCRIPTION OF THE DRAWINGS

FIG. 1 shows a circuit diagram of a digital to analog converter of the invention.

FIGS. 2A and 2B show simulation results of the digital to analog converter of the invention.

FIG. 3 shows a circuit diagram of a digital to analog converter of a conventional art.

FIGS. 4A and 4B show diagrams for explaining an operation of the digital to analog converter of the conventional art.

FIG. 5 shows a waveform chart of a PWM signal.

FIG. 6 shows another circuit diagram of the digital to analog converter of the conventional art.

FIG. 7 shows a bias state of a P-channel type MOS transistor M1 of FIG. 6.

FIGS. 8A and 8B show simulation results of the digital to analog converter of FIG. 6.

### DESCRIPTION OF THE PREFERRED EMBODIMENT

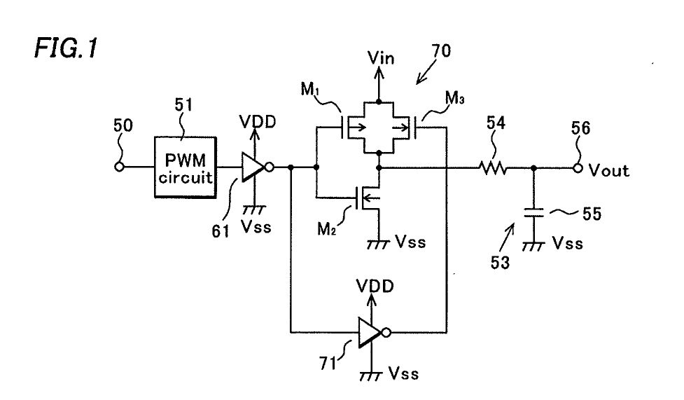

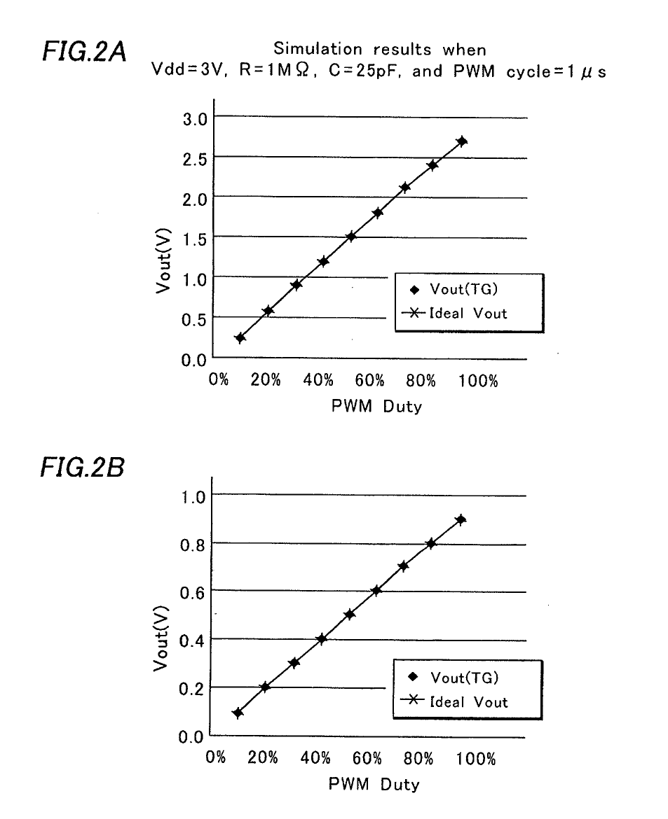

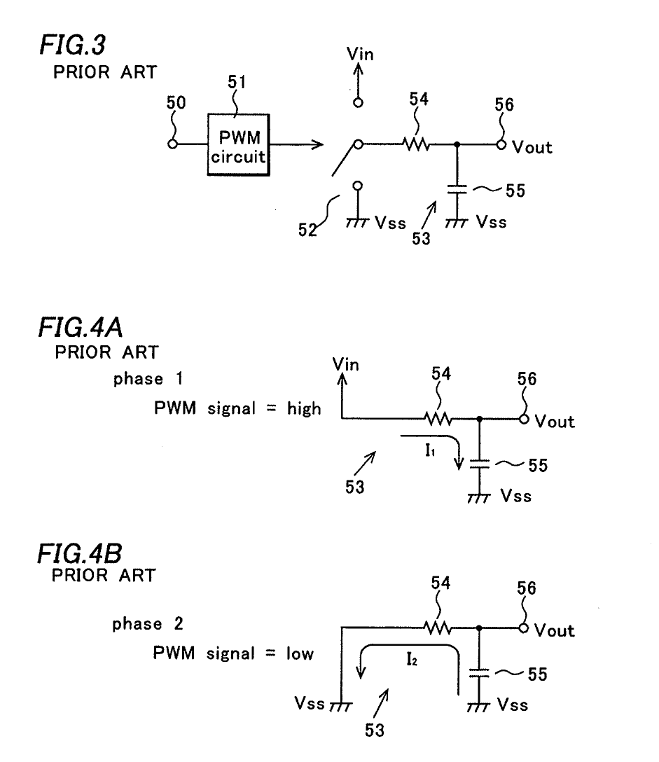

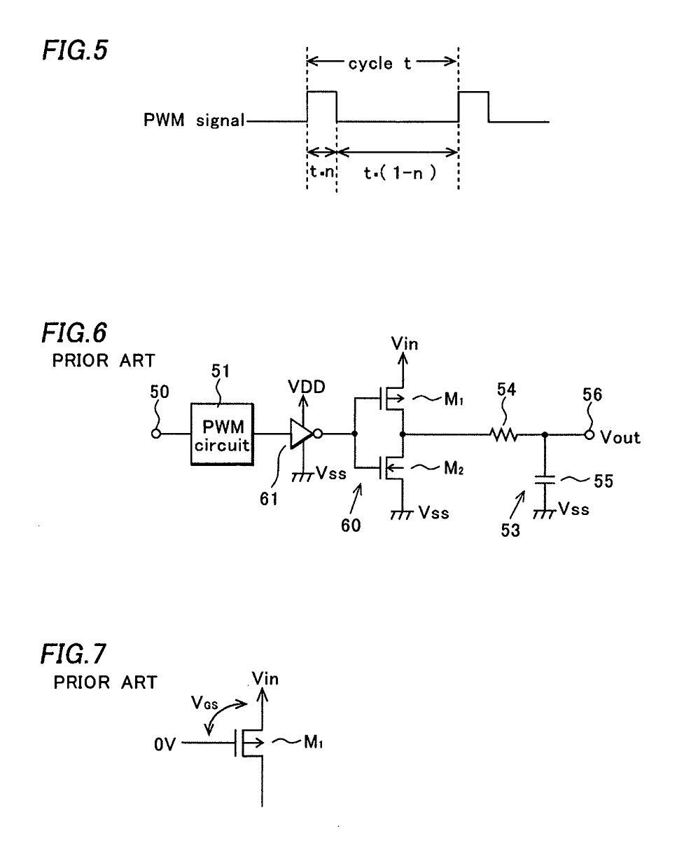

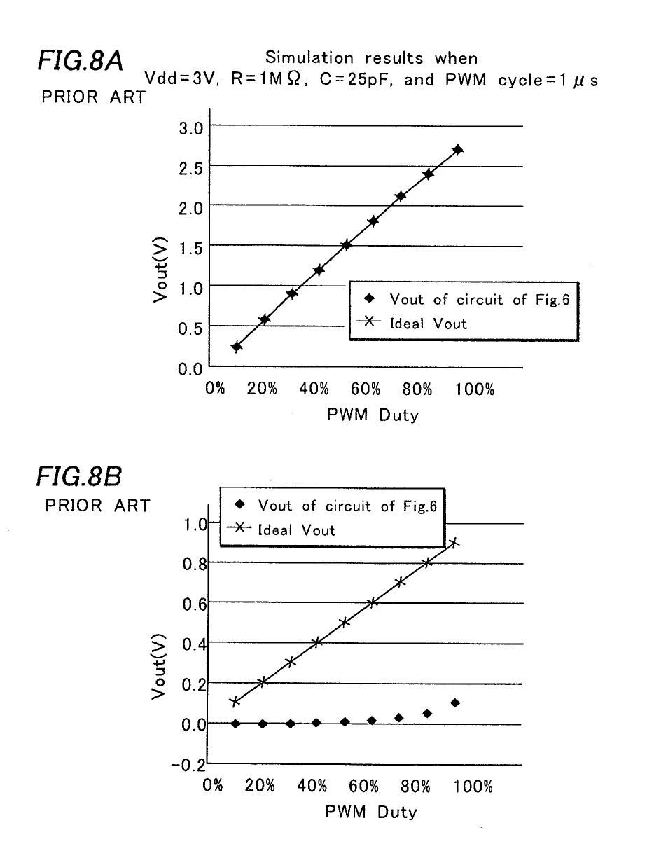

A digital to analog converter of an embodiment of the invention will be described with reference to FIGS. 1-2B. As shown in FIG. 1, in the digital to analog converter of the invention, a CMOS inverter 60 of a circuit shown in FIG. 6 is replaced with a CMOS inverter 70, in which an N-channel type MOS transistor M3 is connected with a P-channel type MOS transistor M1 in parallel. Furthermore, a CMOS inverter 71 inverting an output of a CMOS inverter 61 is provided, and an output of the CMOS inverter 71 is applied to a gate of the N-channel type MOS transistor M3.

In this structure, the P-channel type MOS transistor M1 and the N-channel type MOS transistor M3 form a CMOS transmission gate. A power supply of the CMOS inverter 71 on a high potential side is Vdd, and a power supply thereof on a low potential side is 0V. The other structure is the same as that of the circuit shown in FIG. 6.

In the digital to analog converter of this embodiment, when a PWM signal is high level (on a phase 1), 0V is applied to a gate of the P-channel type MOS transistor M1 and Vdd is applied to the gate of the N-channel type MOS transistor M3, so that both the MOS transistors turn on. On the other hand, when a PWM signal is low level (on a phase 2), Vdd is applied to the gate of the P-channel type MOS transistor M1 and 0V is applied to the gate of the N-channel type MOS transistor M3, so that both the MOS transistors turn off.

Therefore, when an input potential Vin (a power supply of the CMOS inverter 70 on a high potential side) is low, on-state resistance of the P-channel type MOS transistor M1 becomes high, but on-state resistance of the N-channel type MOS transistor M3 becomes low enough. This enables establishment of the equation (1) regardless of high or low input potentials Vin so that an output voltage Vout proportional to a duty ratio can be obtained at any time.

Furthermore, the digital to analog converter of this embodiment is formed by adding one N-channel type MOS transistor M3 and one CMOS inverter 71 to the circuit shown in FIG. 6, so that large-scale modification of the circuit is not needed.

FIGS. 2A and 2B show simulation results showing a relation between the output voltage Vout and the duty ratio n (%) of the PWM signal in the circuit shown in FIG. 1. Vdd=3V, R=1 MΩ, and a PWM cycle=1 μs are set as a common condition. In FIG. 2A, where Vin=3V, the ideal output voltage Vout proportional to the duty ratio of the PWM signal can be obtained. In FIG. 2B, where Vin=1V, the ideal output voltage Vout can be obtained, too.

What is claimed is:

1. A digital to analog converter comprising:
a pulse width modulation circuit generating a pulse having a pulse width corresponding to digital data received by the pulse width modulation circuit;
an inverter receiving the pulse generated by the pulse width modulation circuit; and
a low-pass filter receiving an output of the inverter,
wherein the inverter comprises a P-channel type MOS transistor and a first N-channel type MOS transistor that are connected in series between a high potential and a low potential, the pulse being applied to gates of the P-channel type MOS transistor and the first N-channel type MOS transistor, and the inverter further comprises a second N-channel type MOS transistor that is connected with the P-channel type MOS transistor in parallel to form a CMOS transmission gate comprising the P-channel type MOS transistor and the second N-channel type MOS transistor.

2. The digital to analog converter of claim 1, wherein the high potential is lower than a potential of a high level of the pulse.

3. The digital to analog converter of claim 1, wherein a potential of a high level of the pulse is applied to a gate of the second N-channel type MOS transistor when the third MOS transistor turns on.

4. The digital to analog converter of claim 1, wherein the low-pass filter comprises a resistor and a capacitor.

5. The digital to analog converter of claim 1, further comprising an additional inverter that receives the pulse generated by the pulse width modulation circuit, inverts the received pulse and supplies the inverted pulse to the inverter.
